(19) United States
(12) Patent Application Publication
(10) Pub. No.: US 2020/0168506 A1
(43) Pub. Date: May 28, 2020

(54) METHODS OF FABRICATING SEMICONDUCTOR PACKAGE

(71) Applicant: Lbsemicon Inc., Pyeongtaek-si (KR)

(72) Inventors: Jae Jin Kwon, Hwaseong-si (KR); Jin Kuk Lee, Hwaseong-si (KR)

(73) Assignee: Lbsemicon Inc., Pyeongtaek-si (KR)

(21) Appl. No.: 16/693,298

(22) Filed: Nov. 24, 2019

(30) Foreign Application Priority Data
Nov. 26, 2018 (KR) 10-2018-0147088

(51) Int. Cl. H01L 21/78; H01L 21/56; H01L 23/00; H01L 21/304

(52) U.S. Cl. CPC H01L 21/78; H01L 21/56; H01L 24/11; H01L 24/03; H01L 24/05; H01L 2224/1146; H01L 21/304; H01L 2224/0401; H01L 2224/02381; H01L 2224/13024; H01L 24/13

(57) ABSTRACT

Disclosed is a method of fabricating a semiconductor package, the method including sawing a portion of the thickness of a substrate downward from an upper surface of the substrate along a boundary region between individual chips to form a sawing groove; forming a resin material on the sawing groove and the substrate; removing portions of the resin material to form post spaces on the substrate; filling a conductive material into the post spaces to form posts; respectively forming redistribution layers on the posts; respectively forming insulating film patterns or under bump metal (UBM) patterns on the redistribution layers; respectively bonding solder balls onto the redistribution layers or the UBM patterns; and sawing the resin material to separate into individual chips.

### RELATED APPLICATION

This application claims the benefit of priority of Korean Patent Application No. 10-2018-0147088 filed on Nov. 26, 2018, the contents of which are incorporated herein by reference in their entirety.

### FIELD AND BACKGROUND OF THE INVENTION

The present disclosure relates to a method of fabricating a semiconductor package, and more particularly to a method of fabricating a wafer-level chip-scale package.

The trend in today's electronics industry is to make products that are lighter, smaller, faster, more versatile, more powerful and more reliable at low cost. One of the important technologies that enable the realization of such a product design is package technology, and thus a chip-scale package (CSP) has recently been developed. A chip-scale package is a miniaturized semiconductor package having a semiconductor chip size. Although such a chip-scale package has a significant advantage in terms of size, it still has many drawbacks compared to existing plastic packages. Particularly, a chip-scale package is disadvantageous in that it is difficult to secure reliability, a lot of manufacturing equipment and raw materials are required to fabricate a chip-scale package, and price competitiveness is low due to high manufacturing cost. As a solution to such problems, a wafer-level chip-scale package has attracted attention. When a semiconductor wafer is fabricated according to a general wafer fabrication process, individual chips are separated from the wafer and subjected to a package assembly process. Although the package assembly process requires equipment and raw materials different from those of a wafer fabrication process, thus being a completely different process therefrom, it is possible to fabricate a package as a complete product at a wafer level, i.e., in a state in which individual chips are not separated from a wafer. In addition, existing wafer manufacturing equipment and processes may be used as manufacturing equipment or processes for fabricating the package. Accordingly, the use of raw materials additionally used to fabricate a package can be minimized.

As related art documents, there are Korean Patent Application Publication No. 2007-0077686 (published on Jul. 27, 2007, entitled “Wafer Level Chip Scale Package (WLCSP) including bumppad of NSMD type and manufacturing method thereof”).

### SUMMARY OF THE INVENTION

Therefore, the present disclosure has been made in view of the above problems, and it is one object of the present disclosure to provide a method of fabricating a semiconductor package which capable of preventing crack occurrence on sides of chips during a process of sawing a wafer-level chip-scale package. However, this is only for illustrative purposes, and the scope of the present disclosure is not limited thereto.

In accordance with an aspect of the present disclosure, the above and other objects can be accomplished by the provision of a method of fabricating a semiconductor package, the method including sawing a portion of the thickness of a substrate downward from an upper surface of the substrate along a boundary region between individual chips to form a sawing groove; forming a resin material on the sawing groove and the substrate; removing portions of the resin material to form post spaces on the substrate; filling a conductive material into the post spaces to form posts; respectively forming redistribution layers on the posts; respectively forming insulating film patterns or under bump metal (UBM) patterns on the redistribution layers; respectively bonding solder balls onto the redistribution layers or the UBM patterns; and sawing the resin material to separate into individual chips.

In addition, in the forming, the resin material may be formed to surround an entirety of the sawing groove and an entire upper surface of the substrate, in accordance with the present disclosure.

In addition, the removing may include processing the resin material using at least one selected from among etching, sawing, drilling, laser drilling, through mold via (TMV) processing, and a combination thereof such that pads on the substrate are exposed, in accordance with the present disclosure.

In addition, the method may include, before the sawing of the portion, preparing a substrate having pads formed thereon, in accordance with the present disclosure.

In addition, the sawing of the resin material may include backgrinding the substrate to reduce a thickness of the substrate; and downwardly sawing the resin material formed in the sawing groove to separate into individual chips, in accordance with the present disclosure.

In addition, the backgrinding may include removing all of a bottom surface of the sawing groove and a back surface of the substrate, in accordance with the present disclosure.

In addition, the sawing of the resin material may include only sawing the resin material formed in the sawing groove without contact with the substrate to separate into individual chips, in accordance with the present disclosure.

In addition, the forming of the resin material may include printing or molding an epoxy molding compound (EMC) on the sawing groove and the substrate, in accordance with the present disclosure.

In addition, the semiconductor package may be a wafer-level chip-scale package, in accordance with the present disclosure.

In accordance with another aspect of the present disclosure, there is provided a method of fabricating a semiconductor package, the method including respectively forming posts on pads of a substrate; sawing only a portion of a thickness of the substrate downward from an upper surface of the substrate along a boundary region between individual chips to form a sawing groove; forming a resin material on the sawing groove, an upper surface of the substrate, and the posts; grinding the resin material to expose ends of the posts; respectively forming redistribution layers on the posts; respectively forming insulating film patterns or under bump metal (UBM) patterns on the redistribution layers; respectively bonding solder balls onto the redistribution layers or the UBM patterns; and sawing the resin material to separate into individual chips.

In addition, in the forming of the resin material, the resin material may be formed in a shape of surrounding an entirety of the sawing groove, an upper surface of the substrate, and the posts not to be outwardly exposed, in accordance with the present disclosure.

In addition, the respectively forming of the posts may include forming a photoresist pattern on the substrate such that portions of the pads are exposed; and plating the exposed portions of the pads with a plating material to form the posts, in accordance with the present disclosure.

In addition, the sawing of the resin material may include backgrinding the substrate to reduce a thickness of the substrate; and downwardly sawing the resin material formed in the sawing groove to separate into individual chips, in accordance with the present disclosure.

In addition, the backgrinding may include removing all of a bottom surface of the sawing groove and a back surface of the substrate, in accordance with the present disclosure.

In addition, the sawing of the resin material may include only sawing the resin material formed in the sawing groove without contact with the substrate to separate into individual chips, in accordance with the present disclosure.

In addition, the forming of the resin material may include printing or molding an epoxy molding compound (EMC) on the sawing groove and the substrate, in accordance with the present disclosure.

In addition, the semiconductor package may be a wafer-level chip-scale package, in accordance with the present disclosure.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 illustrates a sectional view of a semiconductor package according to an embodiment of the present disclosure;

FIGS. 2, 3, 4, 5, 6, 7 and 8 are sectional views illustrating a process of fabricating the semiconductor package of FIG. 1;

FIG. 9 is a flowchart illustrating a method of fabricating the semiconductor package of FIG. 1;

FIG. 10 illustrates a sectional view of a semiconductor package according to another embodiment of the present disclosure;

FIGS. 11, 12, 13, 14, 15, 16, 17 and 18 are sectional views illustrating a process of fabricating the semiconductor package of FIG. 10; and

FIG. 19 is a flowchart illustrating a method of fabricating the semiconductor package of FIG. 10.

### DESCRIPTION OF SPECIFIC EMBODIMENTS OF THE INVENTION

Hereinafter, exemplary embodiments of the present disclosure will be described more fully with reference to the accompanying drawings. However, the present disclosure may be embodied in many different forms and should not be construed as limited to the embodiments set forth herein. Rather, these embodiments are provided so that this disclosure will be thorough and complete, and will fully convey the scope of the disclosure to those skilled in the art. For descriptive convenience, the sizes of constituents may be exaggerated or reduced in the drawings.

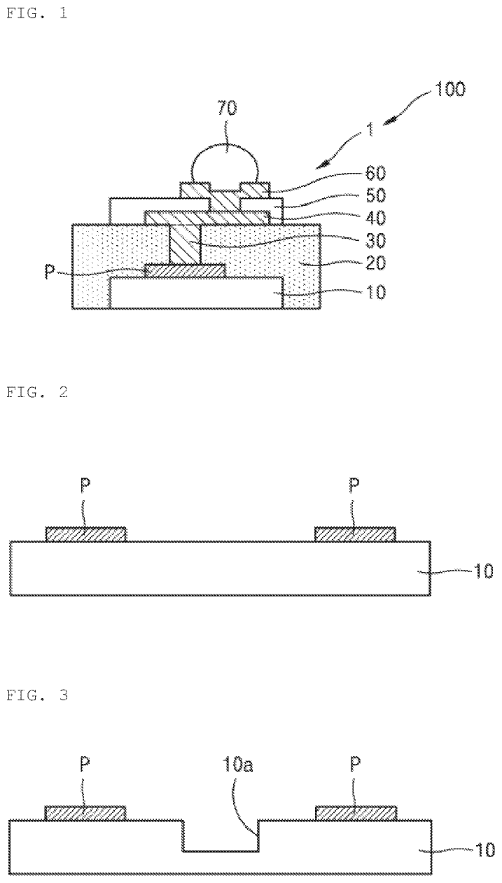

FIG. 1 illustrates a sectional view of a semiconductor package 100 according to an embodiment of the present disclosure.

First, as shown in FIG. 1, the semiconductor package 100 according to an embodiment of the present disclosure may include a substrate 10 such as a wafer or a glass or ceramic substrate; a post 30 formed on a pad P that is disposed on the substrate 10; a resin material 20 surrounding the post and the pad P; a redistribution layer 40 electrically connected to the post 30 and formed on the resin material 20; an insulating film 50 serving to protect the redistribution layer 40; an under bump metal (UBM) 60 formed on the redistribution layer 40; and a solder ball 70 bonded to the UBM 60.

Here, as shown in FIG. 1, the resin material 20 is formed in a shape of surrounding sides and upper surfaces of the substrate 10, thereby preventing crack occurrence on sides of the substrate 10. At the same time, the resin material 20 is disposed under the redistribution layer 40 to reduce the thickness thereof, thereby minimizing side stress of the resin material 20 during sawing.

FIGS. 2 to 8 are sectional views illustrating a process of fabricating the semiconductor package 100 of FIG. 1.

Each step of a process of fabricating the semiconductor package 100 of FIG. 1 is described with reference to FIGS. 2 to 8. First, as shown in FIG. 2, a substrate 10, on which pads P have been formed, may be prepared.

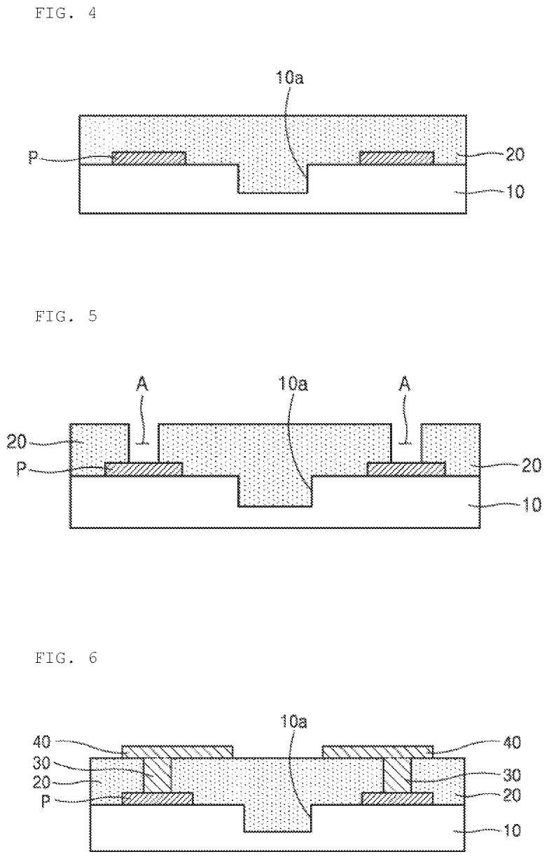

Subsequently, as shown in FIG. 3, a portion of the thickness of the substrate 10 is sawed downward from an upper surface of the substrate 10 along a boundary region between individual chips 1, thereby forming a sawing groove 10a.

Here, the sawing may be half sawing of sawing only a portion or half of the substrate 10.

Subsequently, as shown in FIG. 4, a resin material 20 may be formed on the sawing groove 10a and the substrate 10.

Here, by forming the resin material 20 to surround an entirety of the sawing groove 10a and an entire upper surface of the substrate 10, all of the sides and upper surface of the substrate 10 may be physically, electrically, and electrically solidly protected by the resin material 20.

As a more particular example, an epoxy molding compound (EMC) may be printed or molded on the sawing groove 10a and the substrate 10 so as to form the resin material 20 on the sawing groove 10a and the substrate 10.

Subsequently, as shown in FIG. 5, portions of the resin material 20 may be removed to form post spaces A on the substrate 10.

Here, portions of the resin material 20 may be removed using at least one of etching, sawing, drilling, laser drilling, through mold via (TMV) processing, and a combination thereof such that the pads P on the substrate 10 are exposed. However, the present disclosure is not limited thereto, and the post spaces A may be formed in the resin material 20 using various processing methods.

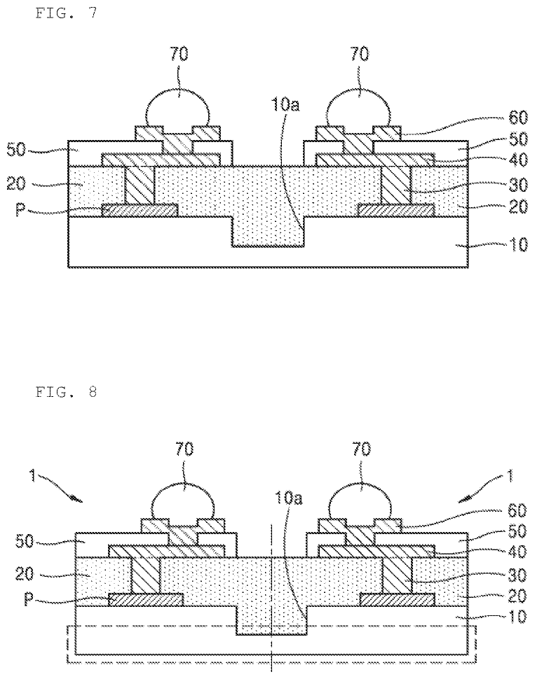

Subsequently, as shown in FIG. 6, a conductive material is filled into the post spaces A to form posts 30, and redistribution layers 40 may be respectively formed on the posts 30.

Subsequently, as shown in FIG. 7, insulating film patterns 50 or under bump metal patterns (UBM) 60 may be respectively formed on the redistribution layers 40, and solder balls 70 may be respectively bonded onto the redistribution layers 40 or the UBM patterns 60.

Here, the insulating film 50 may be, for example, a passivation layer such as a polybenzoxazole (PBO) layer. In addition, polyimide (PI), benzo cyclo butene (BCB), bismaleimide triazine (BT), phenolic resin, epoxy, silicone, an oxide film (SiO₂), a nitride film (Si₂N₄) and equivalents thereof may be used as the insulating film 50.

Subsequently, as shown in FIG. 8, the resin material 20 may be sawed and separated into individual chips 1.

Here, to saw and separate the resin material 20 into the individual chips 1, a backside portion (a dotted box of FIG. 8) of the substrate 10 is ground to reduce the thickness of the substrate 10, and sawing is performed downward along a cut line (an alternate long and short dash line of FIG. 8) formed at the resin material 20 in the sawing groove 10a, thereby separating into the individual chips 1.

Here, in the thinning process of backgrinding the substrate 10 to reduce the thickness thereof, all of a bottom surface of the sawing groove 10a and a back surface of the wafer substrate 10 may be removed.

Subsequently, when the resin material 20 formed in the sawing groove 10a is sawed to separate into the individual chips 1, the resin material 20 may be separated into the individual chips 1 by only sawing the resin material 20 formed in the sawing groove 10a without contact with the substrate 10.

By using the semiconductor package 100, which corresponds to a wafer-level chip-scale package, fabricated according to such a process, crack occurrence on sides of the chip (the substrate 10) in a sawing process thereof may be prevented, and a length of the resin material 20 to be sawed may be reduced, thereby reducing side stress due to sawing.

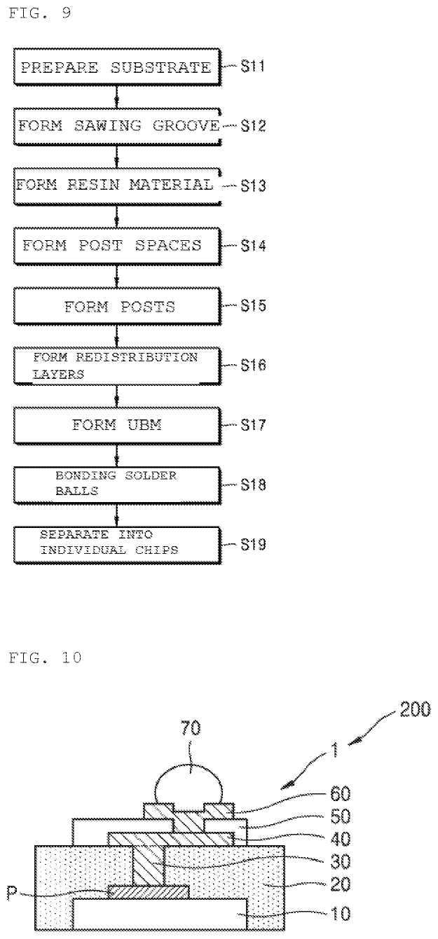

FIG. 9 is a flowchart illustrating a method of fabricating the semiconductor package 100 of FIG. 1.

The method of fabricating the semiconductor package 100 of FIG. 1, which has been described with reference to FIGS. 1 to 9, is now described through a flowchart. A method of fabricating a semiconductor package according to an embodiment of the present disclosure may include a step (S11) of preparing a substrate 10 on which pads P are formed; a step (S12) of sawing a portion of the thickness of the substrate 10 downward from an upper surface of the substrate 10 along a boundary region between individual chips 1 to form a sawing groove 10a; a step (S13) of forming a resin material 20 on the sawing groove 10a and the substrate 10; a step (S14) of removing portions of the resin material 20 to form post spaces A on the substrate 10; a step (S15) of filling a conductive material into the post spaces A to form posts 30; a step (S16) of respectively forming redistribution layers 40 on the posts 30; a step (S17) of respectively forming insulating film patterns 50 or under bump metal (UBM) patterns 60 on the redistribution layers 40; a step (S18) of respectively bonding solder balls 70 onto the redistribution layers 40 or the UBM patterns 60; and a step (S19) of sawing the resin material 20 to separate into individual chips 1.

Here, in the step (S13) of forming the resin material 20 on the sawing groove 10a and the substrate 10, the resin material 20 may be formed to surround an entirety of sides of the sawing groove 10a and an entire upper surface of the substrate 10.

In addition, the step (S14) of removing portions of the resin material 20 to form post spaces A on the substrate 10 may include a step of processing the resin material 20 such that the pads P of the substrate 10 are exposed, using one or more selected from among etching, sawing, drilling, laser drilling, through mold via (TMV) processing, and a combination thereof.

In addition, the step (S19) of sawing the resin material 20 to separate into individual chips 1 may include a step of backgrinding the substrate 10 to reduce the thickness thereof; and a step of downwardly sawing the resin material 20 formed in the sawing groove 10a to separate into individual chips 1.

In addition, the step of backgrinding the substrate 10 to reduce the thickness thereof may include a step of removing all a bottom surface of the sawing groove 10a and a back surface of the wafer substrate 10.

In addition, the step of downwardly sawing the resin material 20 formed in the sawing groove 10a to separate into individual chips 1 may include a step of only sawing the resin material 20 formed in the sawing groove 10a without contact with the substrate 10 to separate into individual chips 1.

In addition, the step (S13) of forming a resin material 20 on the sawing groove 10a and the substrate 10 may include a step of printing or molding an epoxy molding compound (EMC) on the sawing groove 10a and the substrate 10.

In addition, the semiconductor package 100 may be a wafer-level chip-scale package.

FIG. 10 illustrates a sectional view of a semiconductor package 200 according to another embodiment of the present disclosure.

First, as shown in FIG. 10, the semiconductor package 200 according to another embodiment of the present disclosure may include a substrate 10 such as a wafer or a glass or ceramic substrate; a post 30 formed on a pad P that is disposed on the substrate 10; a resin material 20 surrounding the post 30 and the pad P; a redistribution layer 40 electrically connected to the post 30 and formed on the resin material 20; an insulating film 50 serving to protect the redistribution layer 40; an under bump metal (UBM) 60 formed on the redistribution layer 40; and a solder ball 70 bonded to the UBM 60.

Here, as shown in FIG. 10, the resin material 20 is formed in a shape of surrounding sides and upper surfaces of the substrate 10, thereby preventing crack occurrence on sides of the substrate 10. At the same time, the resin material 20 is disposed under the redistribution layer 40 to reduce the thickness thereof, thereby minimizing side stress of the resin material 20 during sawing.

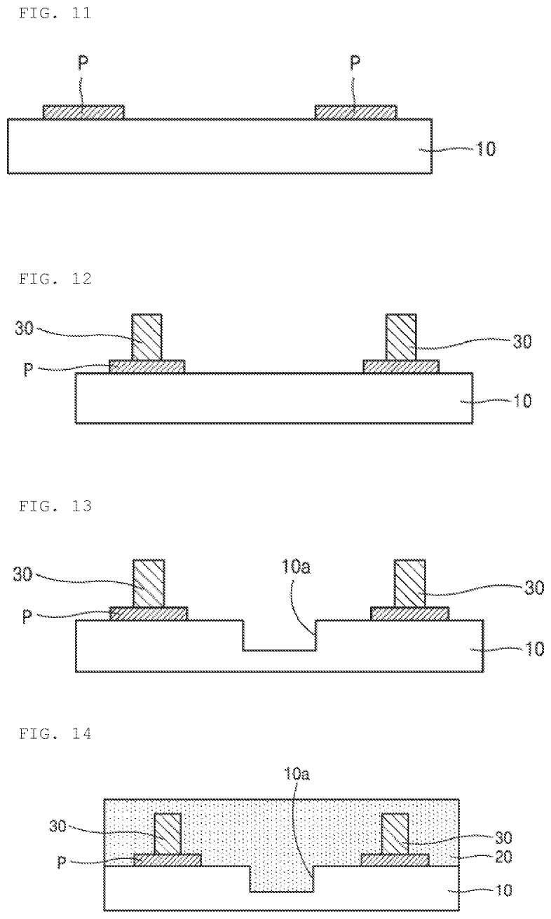

FIGS. 11 to 18 are sectional views illustrating a process of fabricating the semiconductor package 200 of FIG. 10.

Each step of a process of fabricating the semiconductor package 200 of FIG. 10 is described with reference to FIGS. 11 to 18. First, as shown in FIG. 11, a substrate 10 such as a wafer or a glass or ceramic substrate, on which pads P have been formed, may be prepared.

Subsequently, as shown in FIG. 12, posts 30 may be respectively formed on the pads P of the substrate 10.

Here, to form the posts 30, a photoresist pattern is formed on the substrate 10 such that portions of the pads P are exposed, and the exposed portions of the pads P are plated with a plating material.

However, the present disclosure is not limited thereto, and the posts 30 may be formed in various methods such as soldering and bonding.

Subsequently, as shown in FIG. 13, a portion of the thickness of the substrate 10 is sawed downward from an upper surface of the substrate 10 along a boundary region between individual chips 1, thereby forming a sawing groove 10a.

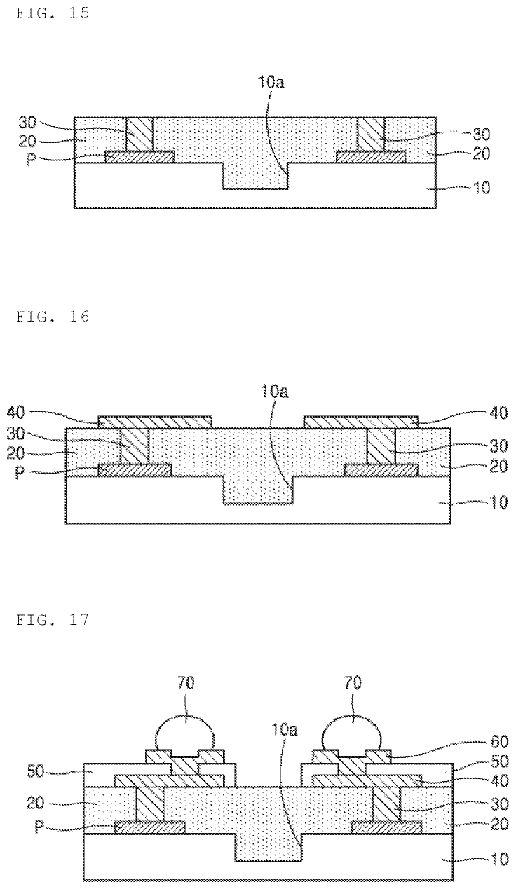

Subsequently, as shown in FIG. 14, a resin material 20 may be formed on the sawing groove 10a, an upper surface of the substrate 10, and the posts 30.

Here, the resin material 20 is formed in a shape of surrounding an entirety of the sawing groove 10a, an upper surface of the substrate 10, and the posts 30 not to be exposed to the outside, and may be formed by printing or molding an epoxy molding compound (EMC) on the sawing groove 10a and an upper surface of the substrate 10.

Subsequently, as shown in FIG. 15, ends of the posts 30 may be exposed by grinding the resin material 20.

Subsequently, as shown in FIG. 16, redistribution layers 40 may be respectively formed on the posts 30.

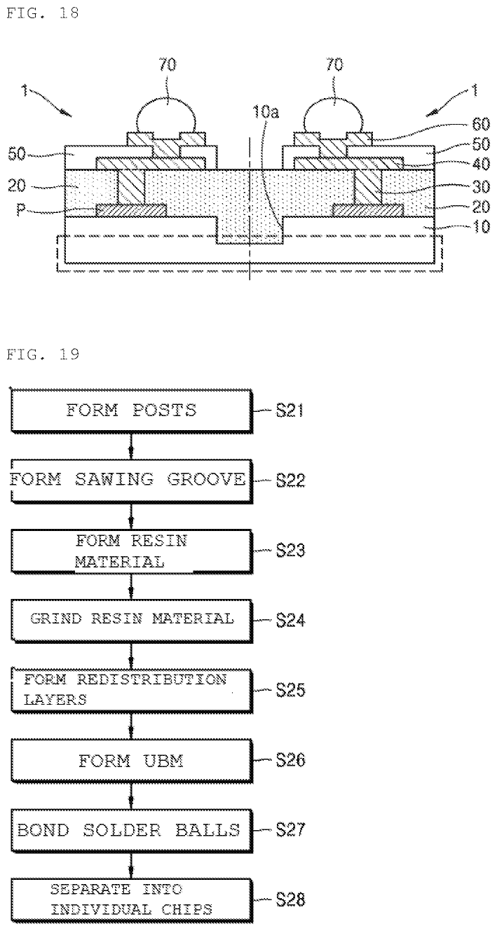

Subsequently, as shown in FIG. 17, insulating film patterns 50 or under bump metal patterns (UBM) 60 may be respectively formed on the redistribution layers 40, and solder balls 70 may be respectively bonded onto the redistribution layers 40 or the UBM patterns 60.

Subsequently, as shown in FIG. 18, the resin material 20 may be sawed and separated into individual chips 1. Here, a backside portion (a dotted box of FIG. 18) of the substrate 10 is ground to reduce the thickness of the substrate 10, and then sawing is performed downward along a cut line (an alternate long and short dash line of FIG. 18) formed at the resin material 20 in the sawing groove 10a, thereby separating into the individual chips 1.

Here, in the thinning process of backgrinding the substrate 10 to reduce the thickness thereof, all of a bottom surface of the sawing groove 10a and a back surface of the substrate 10 may be removed.

In addition, when the resin material 20 formed in the sawing groove 10a is sawed, the resin material 20 may be separated into the individual chips 1 by only sawing the resin material 20 formed in the sawing groove 10a without contact with the substrate 10.

By using the semiconductor package 200, which corresponds to a wafer-level chip-scale package, fabricated according to such a process, crack occurrence on sides of the chip (the substrate 10) in a sawing process thereof may be prevented, and a length of the resin material 20 to be sawed may be reduced, thereby reducing side stress due to sawing.

FIG. 19 is a flowchart illustrating a method of fabricating the semiconductor package 200 of FIG. 10.

The method of fabricating the semiconductor package 200 of FIG. 10 which has been described with reference to FIGS. 10 to 19 is now described through a flowchart. A method of fabricating a semiconductor package according to an embodiment of the present disclosure may include a step (S21) of respectively forming posts 30 on pads P of a substrate 10; a step (S22) of sawing only a portion of the thickness of the substrate 10 downward from an upper surface of the substrate 10 along a boundary region between individual chips to form a sawing groove 10a; a step (S23) of forming a resin material 20 on the sawing groove 10a, an upper surface of the substrate 10, and the posts 30; a step (S24) of grinding the resin material 20 to expose ends of the posts 30; a step (S25) of respectively forming redistribution layers 40 on the posts 30; a step (S26) of respectively forming insulating film patterns 50 or under bump metal (UBM) patterns 60 on the redistribution layers 40; a step (S27) of respectively bonding solder balls 70 onto the redistribution layers 40 or the UBM patterns 60; and a step (S28) of sawing the resin material 20 to separate into individual chips 1.

Here, in the step (S23) of forming a resin material 20 on the sawing groove 10a, an upper surface of the substrate 10, and the posts 30, the resin material 20 may be formed in a shape of surrounding an entirety of the sawing groove 10a, an upper surface of the substrate 10, and the posts 30 not to be exposed to the outside.

In addition, the step (S21) of respectively forming posts 30 on pads P of a substrate 10 may include a step of forming a photoresist pattern on the substrate 10 such that portions of the pads P are exposed; and a step of plating the exposed portions of the pads P with a plating material to form posts 30.

In addition, the step (S28) of sawing the resin material 20 to separate into individual chips 1 may include a step of backgrinding the substrate 10 to reduce the thickness thereof; and a step of downwardly sawing the resin material 20 formed in the sawing groove 10a to separate into individual chips 1.

In addition, the step of backgrinding the substrate 10 to reduce the thickness thereof may include a step of removing all a bottom surface of the sawing groove 10a and a back surface of the substrate 10.

In addition, the step (S28) of downwardly sawing the resin material 20 formed in the sawing groove 10a to separate into individual chips 1 may include a step of only sawing the resin material 20 formed in the sawing groove 10a without contact with the substrate 10 to separate into individual chips 1.

In addition, the step (S23) of forming a resin material 20 on the sawing groove 10a, an upper surface of the substrate 10, and the posts 30 may include a step of printing or molding an epoxy molding compound (EMC) on the sawing groove 10a and the substrate 10.

As apparent from the above description, the present disclosure provides a method of fabricating a semiconductor package which is capable of preventing crack occurrence on sides of chips during a process of sawing a wafer-level chip-scale package and reducing a length to be sawed, thereby lowering side stress due to sawing. However, the scope of the present disclosure is not limited to the effects.

While the present disclosure has been particularly shown and described with reference to exemplary embodiments thereof, it will be understood by those of ordinary skill in the art that various changes in form and details may be made therein without departing from the spirit and scope of the present disclosure. Therefore, the true technical protection scope of the present disclosure should be defined by the technical spirit of the appended claims.

What is claimed is:

1. A method of fabricating a semiconductor package, the method comprising:
sawing a portion of thickness of a substrate downward from an upper surface of the substrate along a boundary region between individual chips to form a sawing groove;
forming a resin material on the sawing groove and the substrate;
removing portions of the resin material to form post spaces on the substrate;
filling a conductive material into the post spaces to form posts;
respectively forming redistribution layers on the posts;
respectively forming insulating film patterns or under bump metal (UBM) patterns on the redistribution layers;
respectively bonding solder balls onto the redistribution layers or the UBM patterns; and
sawing the resin material to separate into individual chips.

2. The method according to claim 1, wherein, in the forming, the resin material is formed to surround an entirety of the sawing groove and an entire upper surface of the substrate.

3. The method according to claim 1, wherein the removing comprises processing the resin material using at least one selected from among etching, sawing, drilling, laser drilling, through mold via (TMV) processing, and a combination thereof such that pads on the substrate are exposed.

4. The method according to claim 1, comprising, before the sawing of the portion, preparing a substrate having pads formed thereon.

5. The method according to claim 1, wherein the sawing of the resin material comprises:
backgrinding the substrate to reduce a thickness of the substrate; and
downwardly sawing the resin material formed in the sawing groove to separate into individual chips.

6. The method according to claim 5, wherein the backgrinding comprises removing all of a bottom surface of the sawing groove and a back surface of the substrate.

7. The method according to claim 6, wherein the sawing of the resin material comprises only sawing the resin material formed in the sawing groove without contact with the substrate to separate into individual chips.

8. The method according to claim 1, wherein the forming of the resin material comprises printing or molding an epoxy molding compound (EMC) on the sawing groove and the substrate.

9. The method according to claim 1, wherein the semiconductor package is a wafer-level chip-scale package.

10. A method of fabricating a semiconductor package, the method comprising:
respectively forming posts on pads of a substrate;
sawing only a portion of a thickness of the substrate downward from an upper surface of the substrate along a boundary region between individual chips to form a sawing groove;
forming a resin material on the sawing groove, an upper surface of the substrate, and the posts;
grinding the resin material to expose ends of the posts;
respectively forming redistribution layers on the posts;
respectively forming insulating film patterns or under bump metal (UBM) patterns on the redistribution layers;
respectively bonding solder balls onto the redistribution layers or the UBM patterns; and
sawing the resin material to separate into individual chips.

11. The method according to claim 10, wherein, in the forming of the resin material, the resin material is formed in a shape of surrounding an entirety of the sawing groove, an upper surface of the substrate, and the posts not to be outwardly exposed.

12. The method according to claim 10, wherein the respectively forming of the posts comprises:
forming a photoresist pattern on the substrate such that portions of the pads are exposed; and
plating the exposed portions of the pads with a plating material to form the posts.

13. The method according to claim 10, wherein the sawing of the resin material comprises:
backgrinding the substrate to reduce a thickness of the substrate; and
downwardly sawing the resin material formed in the sawing groove to separate into individual chips.

14. The method according to claim 13, wherein the backgrinding comprises removing all of a bottom surface of the sawing groove and a back surface of the substrate.

15. The method according to claim 10, wherein the sawing of the resin material comprises only sawing the resin material formed in the sawing groove without contact with the substrate to separate into individual chips.

16. The method according to claim 10, wherein the forming of the resin material comprises printing or molding an epoxy molding compound (EMC) on the sawing groove and the substrate.

17. The method according to claim 10, wherein the semiconductor package is a wafer-level chip-scale package.
